(19) United States
(12) Patent Application Publication
(10) Pub. No.: US 2016/0329324 A1
(43) Pub. Date: Nov. 10, 2016

(54) Bidirectional Bipolar Power Devices with Two-Surface Optimization of Striped Emitter/Collector Orientation

(71) Applicant: Ideal Power Inc., Austin, TX (US)

(72) Inventor: Richard A. Blanchard, Los Altos, CA (US)

(21) Appl. No.: 15/090,611

(22) Filed: Apr. 4, 2016

Related U.S. Application Data
(60) Provisional application No. 62/142,022, filed on Apr. 2, 2015.

(51) Int. Cl. H01L 27/082; H01L 29/10; H01L 29/08; H01L 29/16; H01L 29/40

(52) U.S. Cl. CPC H01L 27/082; H01L 29/16; H01L 29/407; H01L 29/0804; H01L 29/0821; H01L 29/1004

(57) ABSTRACT

Two-surface bidirectional power bipolar transistors, in which the emitter/collector regions on the opposite surfaces of the die are each laid out as an array of stripes, and the stripes on opposite surfaces are not parallel to each other. Instead, the emitter/collector stripes on one surface, if projected normal to the surfaces, would define a pattern on the opposite surface which is orthogonal to the actual layout of stripes on that surface.

### CROSS-REFERENCE

Priority is claimed from U.S. provisional 62/142,022, which is hereby incorporated by reference.

### BACKGROUND

The present application relates to bidirectional bipolar transistors which have separate base contact regions, as well as separate emitter/collector diffusions, on both surfaces of a monolithic semiconductor die.

Note that the points discussed below may reflect the hindsight gained from the disclosed inventions, and are not necessarily admitted to be prior art.

Bi-directional bipolar transistors or “B-TRANs” have been proposed for use as high voltage bi-directional switches, based on their low on-voltages at high current levels. Earlier patent applications of Ideal Power Inc., many of which are now issued, have described many features of B-TRAN devices and methods, including many options, improvements, and alternatives. For example, see U.S. Pat. Nos. 9,029,909, 9,190,894, 9,203,400, 9,203,401, and 9,209,713, all of which are hereby incorporated by reference; also see pending U.S. application Ser. Nos. 14/566,576, 14/599,191, 14/882,316, 14/918,440, 14/937,814, 14/992,971, 14/935,344, 15/018,844, 15/055,514, 15/083,217, and 15/083,230. All of these applications and patents, and all their direct and indirect priority applications, are hereby incorporated by reference.

Note that many of these applications refer to the p-type regions on either surface as “base contact regions.” However, to avoid confusion, these regions are now being referred to as “base connection regions.”

High voltage, bi-directional devices that are fabricated with masked regions on both sides of the wafer using trench technology include power MOSFETs, IGBTs, and bipolar transistors. While the use of trench technology increases current density and provides other advantages, such as offering the possibility of having another level of interconnection, the use of trench technology can also cause mechanical problems such as wafer bowing. Such wafer bowing is believed to be the result of the forces that occur when trenches are filled with one or more materials such as silicon dioxide, silicon nitride, or doped polycrystalline silicon. Silicon dioxide and silicon nitride both have coefficients of thermal expansion that differ from that of silicon, and are formed in the trenches at elevated temperatures. As the wafers cool to room temperature from the processing temperature, this difference in expansion or contraction is believed to cause wafer bowing. In addition, as the physical size of devices fabricated using trench technology increases, the percentage of the surface area of a device that actually contains trenches also increases. Wafer thickness is also an important factor, since bi-directional devices typically need to be much thinner than the starting wafer. It follows that a large device fabricated with trenches on a considerable percentage of both surfaces may experience wafer warping.

Bi-directional bipolar transistors or “B-TRANs” have been proposed for use as high voltage bi-directional switches, based on their low on-voltages at high current levels. One concern in the actual fabrication of a high voltage B-TRAN is the design of a termination structure capable of withstanding the rated voltage without significantly increasing the cost of the device. A number of possible high voltage termination structures exist, but the goal of this work was to determine whether there are any high voltage termination structures that can be fabricated using the same process steps as those used to fabricate the B-TRAN structure. The structure of an NPN B-TRAN device is shown in FIG. 1B while one possible circuit symbol for this device is shown in FIG. 2.

An enhancement to the B-TRAN structure of FIG. 1B is shown in FIG. 3. In this figure, the trench that was filled with dielectric in FIG. 1B has a trench lined with a dielectric like silicon dioxide, and is subsequently filled with conductive polycrystalline silicon. The polycrystalline silicon electrode located in each trench is in turn electrically connected to the n-type emitter diffusion region present on at least one side of the trench.

FIG. 4 shows a cross section of a B-TRAN device, including a portion of the termination region of the structure.

FIG. 5A is a drawing of a wafer having large dice, with all of the dice having trenches parallel to the wafer flat. (In this application, the orientation of the trenches is referenced to the direction of the wafer flat.) This warping, if too great, can make it impossible to process the wafers, particularly through the photomasking step, which require wafers having only a small variation from being completely flat.

### Bidirectional Bipolar Power Devices with Two-Surface Optimization of Striped Emitter/Collector Orientation

The present application teaches, among other innovations, a layout for two-surface bidirectional power bipolar transistors. The emitter/collector regions on the opposite surfaces of the die are each laid out as an array of stripes. Each stripe of the emitter/collector is surrounded by an insulating trench, which may contain a field plate. Stripes of base connection region (e.g. p-type) are interposed between the stripes of the emitter/collector regions. Since the elongated emitter/collector regions are bordered by insulating trenches, the insulating trenches are parallel to each other. The present application teaches that the orientations of the emitter/collector regions are controlled to avoid cumulation of stress. Two independent techniques are disclosed, and they can be used separately or together. In one technique, the orientations of the emitter/collector stripes on an undiced wafer are orthogonal between the corresponding surfaces of adjacent dice; in the other technique, the orientations of the emitter/collector stripes on each die are different (and preferably orthogonal) between the front and back surfaces of each die.

### BRIEF DESCRIPTION OF THE DRAWINGS

The disclosed inventions will be described with reference to the accompanying drawings, which show important sample embodiments and which are incorporated in the specification hereof by reference, wherein:

FIG. 1A shows corresponding plan and section views of a new B-TRAN device.

FIG. 1B shows the structure of an example of a B-TRAN device.

FIG. 1C shows a view through to the other side of the device of FIG. 1B.

FIG. 1D shows one sample embodiment of B-TRAN dice arrangements.

FIG. 2 shows a possible circuit symbol for the device of FIG. 1B.

FIG. 3 shows an enhancement to the B-TRAN structure of FIG. 1B.

FIG. 4 shows a cross section of a B-TRAN device, including a portion of the termination region of the structure.

FIGS. 5A, 5B, and 5C show alternative sample embodiments of B-TRAN dice arrangements.

### DETAILED DESCRIPTION OF SAMPLE EMBODIMENTS

The numerous innovative teachings of the present application will be described with particular reference to presently preferred embodiments (by way of example, and not of limitation). The present application describes several inventions, and none of the statements below should be taken as limiting the claims generally.

The present application provides several alternative techniques for fabricating wafers that are acceptably flat for all process steps, even though trench technology is used in their fabrication. The key to the proposed solutions is to obtain a balance between the forces resulting from the trenches, by fabricating approximately one-half of the die with their trenches perpendicular to the wafer flat, while the other one-half have their trenches parallel to the wafer flat. This goal may be met as follows:

1. Use a square die so the orientation of each device may be chosen to minimize wafer stress.

2. Position each die on the two wafer surfaces so the stresses across the wafer and the stresses on both sides of the same die are balanced.

3. Though not required, a device layout that is symmetrical about its central axis results in die that have equivalent surfaces, and do not need to be kept track of following wafer singulation.

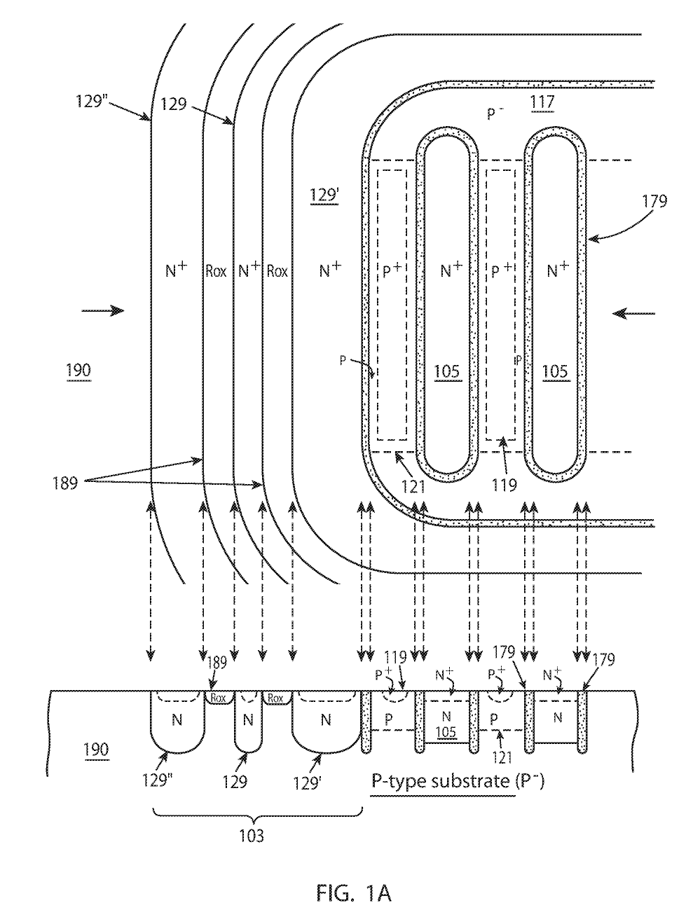

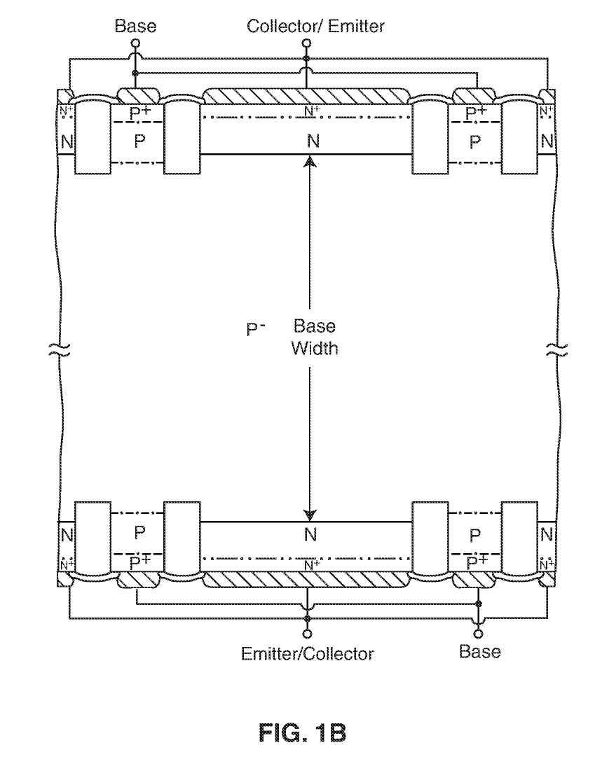

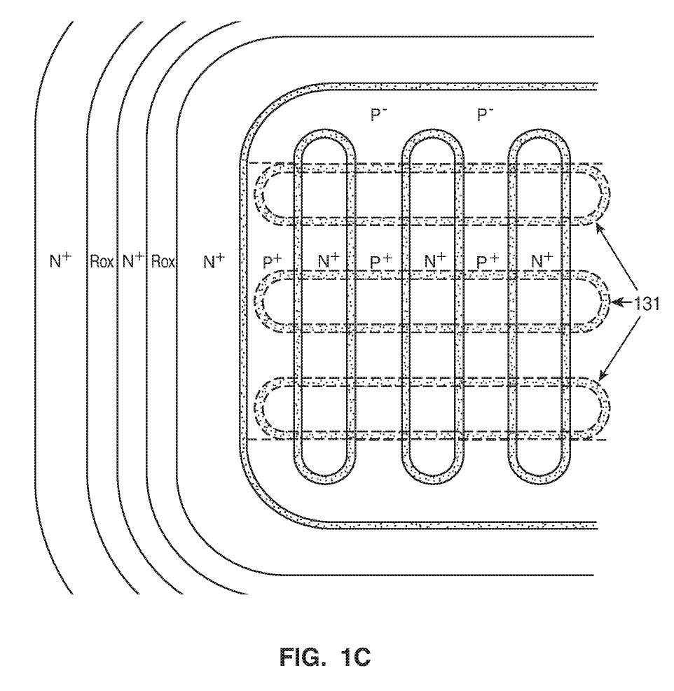

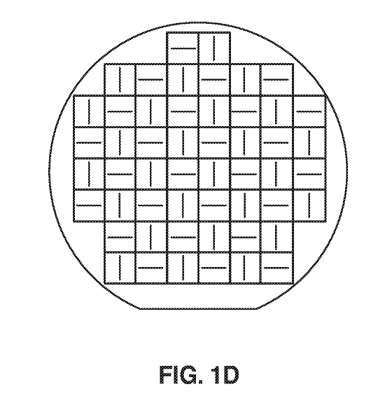

FIG. 1A shows a top view of the B-TRAN device as well as a cross section of the device. FIG. 1A shows that the termination region 103 uses the same diffused regions that form the emitter/collector regions of the B-TRAN. Specifically:

1. The diffused field-limiting rings 129 are formed by the same doping and diffusion steps as the B-TRAN emitter/collector regions 105. The use of diffused regions formed by the same step reduces the number of steps in the fabrication sequence.

2. Both the emitter regions 105 and the diffused n-type regions that form the field-limiting rings 129 preferably include both deep and shallow n-type doping components, formed by implanting both phosphorus and arsenic into the p-type substrate using the same mask. This process sequence saves the use of one masking layer, while also providing a deep n-type junction capable of withstanding a high voltage, as well as a shallow, heavily doped n++ region at the surface that forms a low resistance ohmic contact with the metal layer.

In one example, the two n-type dopants are phosphorus and arsenic, and each is implanted at a dose of 2 or 3×10¹⁵ cm⁻². Arsenic will have a shorter diffusion length than phosphorus (in silicon, for a given thermal history), so that the emitter/collector regions have both a high concentration at shallow depths, and a reasonably large junction depth.

Optionally an additional shallow n++ “plug” implant can be used to minimize specific contact resistance.

Optionally antimony can be substituted for arsenic if desired.

The example shown in FIG. 1A includes, among the field-limiting rings 129, an innermost field-limiting ring 129′ and an outermost field-limiting ring 129″. For clearer illustration, only three field-limiting rings 129 are shown in FIG. 1A, but this is simplified. In a currently preferred example, ten field-limiting rings 129 are used, including eight rings 129 between the innermost field-limiting rings 129′ and the outermost field-limiting ring 129″.

In this example, the widest one of the field-limiting rings 129 is the innermost field-limiting ring 129′. The outermost field-limiting ring 129″ is also wider than the other ones of the field-limiting rings 129.

In this example, recessed oxide regions 189 (“Rox”) are interposed between adjacent field limiting rings 129. Recessed oxide regions 189 can be formed using a “LOCOS” process, or alternatively by etching a trench, filling with oxide, and then planarizing the wafer using CMP. For example, this can be done by etching about ½ micron of silicon, growing about 1.1 micron of SiO₂, and then planarizing using CMP.

Another way to form the recessed oxide regions 189 is by etching trenches to the full desired depth of the recessed oxide regions 189 (here about 1.1 microns deep), filling the trenches using a TEOS oxide, using a modified reverse mask to remove most of the deposited oxide that is not over the trenches, and then using CMP to planarize the wafer.

In both these examples (but not necessarily in every implementation), the recessed oxide regions 189 are not associated with the field plates which can be emplaced in the trenches 179. The field plates are formed of poly silicon, later in the process.

The thickness of the recessed oxide regions 189, in this example, is selected to be slightly more than a micron. Smaller thickness values can degrade the long term reliability of the device.

Another criterion for optimization of this particular process is local planarity. Since a handle wafer will be bonded to each side of the wafer (in the preferred process), the recessed oxide regions 189 need to be planar, to avoid degrading bondability.

Another criterion for optimization of this particular process is wafer flatness. The process of forming the recessed oxide regions 189 should not impart warping or bowing of the wafer (as may be caused by accumulation of stress from local pattern features).

Note also, in FIG. 1A, that each emitter/collector region 105 is shaped like a stripe, and is bordered, along its long sides, by a p+ base contact region 119 inside p-type base contact border region 121. The short side of each emitter/collector region 105 is bordered by p− base region 117. This is useful in optimizing the emitter/collector regions to have uniform turnoff, and to have fairly uniform on-state current density across their width.

The dopant profile of the base contact regions 119 is preferably formed by several diffusion components. The background wafer doping, in this example, is p-type. In addition, two implantations of boron and/or boron difluoride dopants are used, in a preferred example, to achieve good contact resistance and reduce the series resistance from the contact area to the p-type substrate. The total p-type doping introduced into the base contact areas 119, in this example, is around 2×10¹⁵ cm⁻².

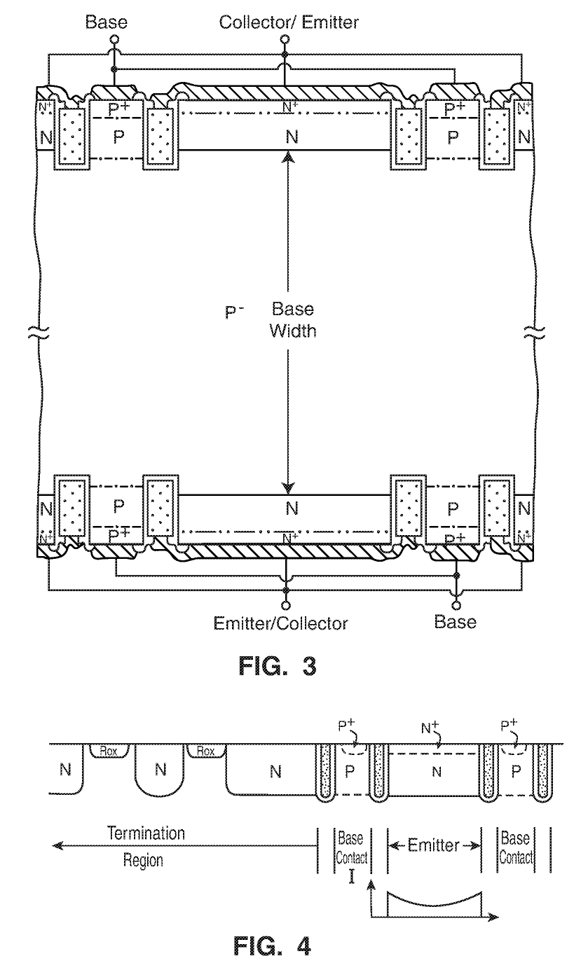

The base-to-emitter/collector isolation trenches 179, in this example, can include insulated polysilicon field plates which are electrically connected to the adjacent n-type emitter/collector region. However, other separation structures can be used, e.g. dielectric-filled trenches as shown in FIG. 3.

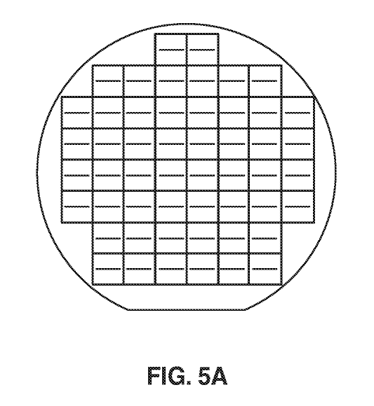

Note also that, in FIG. 4, the shallowest p++ diffusion stops short of borders of the base contact area 119. This keeps the lateral tail of the base contact doping from modifying the doping of the field plate in the trench 179. The p− regions are simply the doped substrate; the p regions have been implanted and diffused to about 3 microns; and the P+ regions are doped by an implant performed through the contact mask opening, to assure a low contact resistance to the P region. Thus in this example the p+ regions are set back from the poly field plate, while the p regions are not.

FIG. 1A also shows inventive features which allow for efficient mobile carrier injection when the N+/N− emitter/collector regions on one surface are forward biased (thereby acting as the emitter), and provide a high breakdown voltage when the same regions are reverse biased (and acting as the collector).

1. Each emitter/collector region is completely surrounded by a trench that has a liner of a dielectric layer or a dielectric sandwich and is filled with doped polycrystalline silicon. An electrical connection is also made between the polycrystalline silicon in the trench and the emitter region.

2. There is P+ dopant adjacent to the trench along the majority of its two straight sides. The presence of the P+ dopant in these regions provides a low resistance path to the portion of the base contact region adjacent to the emitter/collector region, thereby decreasing the base resistance. The p+ region can also be extended to completely surround the racetrack, filling the entire region between the racetracks and the poly-filled perimeter trench. (The perimeter poly-filled trench provides a transition region between the interior “active” region of the B-TRAN and the edge termination region.)

Ways of obtaining an acceptable balance of stresses include positioning the die on a wafer in one of several patterns. For instance, FIG. 1D shows one side of a wafer where adjacent dice on the same surface have their trenches perpendicular to each other. The pattern on each die on the second side of the wafer could have the same trench orientation, of could have a trench orientation that is 90 degrees from that on the first side of the wafer. The first option would balance the stresses on each side of every die, while in the second option, the silicon on the second side of each die would resist bowing, since the trenches on the first side are perpendicular to those on the second side.

FIG. 1C shows a through-device view of a die like that of FIG. 1A, where the dice are arranged like in FIG. 1D. Field plate trenches 131, on the far side of the die, correspond to field plate trenches 179 on the near side of the die, and the rest of the far-side die is rotated correspondingly.

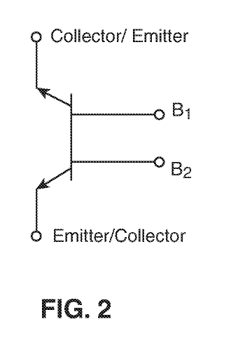

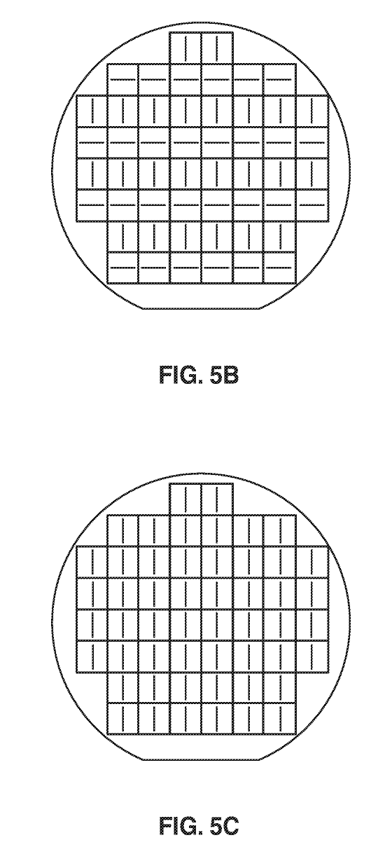

Another variation is shown in FIG. 5B, which has alternate rows of devices with trenches that are at 90 degrees with respect to each other. The pattern of alternating rows might not resist bowing as effectively as the pattern of FIG. 2, but it might be sufficient, particularly if the pattern of FIG. 3 is used on both sides of the wafer. In this instance, each die would have the same trench pattern on both the first side and the second side of the wafer, so the stress on both sides of each die would be equal.

FIG. 5C has a pattern similar to that of FIG. 1, but with the trenches of each die perpendicular the wafer flat. In this example with the pattern of FIG. 1 on the first surface and the pattern of FIG. 2 on the second surface, all of the die on each side of the wafer have the same orientation, but each die has trenches that are perpendicular to each other on its first and second surfaces.

Other die patterns besides those in the examples above can be used on each wafer surface to keep bowing to an acceptable level. No problems with device operation result from having the pattern on the two surfaces of each die perpendicular to each other. The current still flows through the die from one surface to the other. The only concern is that of packaging the die. The bonding regions on each surface may be in the same locations, or may be at 90 degrees with respect to each other. Once a die pattern for each surface has been selected, information about the bonding pad location on each surface of the die must be provided to the designer of the package.

Geometrically, the two surfaces of a die (or wafer) are parallel but not coplanar. It is thus somewhat approximate to describe stripes on one surface as orthogonal to those on the other. More precisely, we can say that the emitter/collector stripes on one surface, if projected normal to the surfaces, would define a pattern on the opposite surface which is orthogonal to the actual layout of stripes on that surface

### Advantages

The disclosed innovations, in various embodiments, provide one or more of at least the following advantages. However, not all of these advantages result from every one of the innovations disclosed, and this list of advantages does not limit the various claimed inventions.
Lower incidence of bowing.
Fewer stress-dependent variations.
Easier lithography.
Higher yield.

According to some but not necessarily all embodiments, there is provided: A bidirectional power bipolar transistor device, comprising: a semiconductor die having, on both first and second surfaces thereof, both a respective plurality of elongated first-conductivity-type emitter/collector regions, each of which is laterally surrounded by a first insulating trench, and a respective plurality of elongated second-conductivity-type base connection regions which are interposed between adjacent pairs of the elongated first-conductivity-type emitter/collector regions; wherein the elongated first-conductivity-type emitter/collector regions on the first surface of the die are orthogonal to the elongated first-conductivity-type emitter/collector regions on the second surface of the die.

According to some but not necessarily all embodiments, there is provided: A bidirectional power bipolar transistor device, comprising: a semiconductor die having, on both first and second surfaces thereof, both a respective plurality of elongated first-conductivity-type emitter/collector regions, each of which is laterally surrounded by a first insulating trench, and a respective plurality of elongated second-conductivity-type base connection regions which are interposed between adjacent pairs of the elongated first-conductivity-type emitter/collector regions, and which provide ohmic contact to the second-conductivity-type bulk of the semiconductor die; wherein the elongated first-conductivity-type emitter/collector regions on the first surface of the die are orthogonal to the elongated first-conductivity-type emitter/collector regions on the second surface of the die; and first and second current-carrying metallizations, which make contact to the emitter/collector regions on the first and second surfaces respectively; and first and second additional metallizations, which make contact to the base connection regions on the first and second surfaces respectively.

According to some but not necessarily all embodiments, there is provided: a symmetrically-bidirectional power bipolar transistor device, comprising: a p-type semiconductor die having, on both first and second surfaces thereof, both a respective plurality of elongated n-type emitter/collector regions, each of which is laterally surrounded by a first insulating trench, and a respective plurality of elongated p-type base connection regions which are interposed between adjacent pairs of the elongated n-type emitter/collector regions, and are insulated from the emitter/collector regions by the first insulating trench; wherein the elongated n-type emitter/collector regions on the first surface of the die are orthogonal to the elongated n-type emitter/collector regions on the second surface of the die.

According to some but not necessarily all embodiments, there is provided: two-surface bidirectional power bipolar transistors, in which the emitter/collector regions on the opposite surfaces of the die are each laid out as an array of stripes, and the stripes on opposite surfaces are not parallel to each other. Instead, the emitter/collector stripes on one surface, if projected normal to the surfaces, would define a pattern on the opposite surface which is orthogonal to the actual layout of stripes on that surface.

### Modifications and Variations

As will be recognized by those skilled in the art, the innovative concepts described in the present application can be modified and varied over a tremendous range of applications, and accordingly the scope of patented subject matter is not limited by any of the specific exemplary teachings given. It is intended to embrace all such alternatives, modifications and variations that fall within the spirit and broad scope of the appended claims.

None of the description in the present application should be read as implying that any particular element, step, or function is an essential element which must be included in the claim scope: THE SCOPE OF PATENTED SUBJECT MATTER IS DEFINED ONLY BY THE ALLOWED CLAIMS. Moreover, none of these claims are intended to invoke paragraph six of 35 USC section 112 unless the exact words “means for” are followed by a participle.

The claims as filed are intended to be as comprehensive as possible, and NO subject matter is intentionally relinquished, dedicated, or abandoned.

What is claimed is, among others (and, without exclusion, in addition to any other points which are indicated herein as inventive and/or surprising and/or advantageous):

1. A bidirectional power bipolar transistor device, comprising:
a semiconductor die having, on both first and second surfaces thereof, both
a respective plurality of elongated first-conductivity-type emitter/collector regions, each of which is laterally surrounded by a first insulating trench, and
a respective plurality of elongated second-conductivity-type base connection regions which are interposed between adjacent pairs of the elongated first-conductivity-type emitter/collector regions;
wherein the elongated first-conductivity-type emitter/collector regions on the first surface of the die are orthogonal to the elongated first-conductivity-type emitter/collector regions on the second surface of the die.

2. The device of claim 1, wherein the first insulating trench includes a conductive field plate therein, which is electrically tied to the emitter/collector region.

3. The device of claim 1, wherein the first conductivity type is n-type.

4. The device of claim 1, wherein the semiconductor die is silicon.

5. A bidirectional power bipolar transistor device, comprising:
a semiconductor die having, on both first and second surfaces thereof, both
a respective plurality of elongated first-conductivity-type emitter/collector regions, each of which is laterally surrounded by a first insulating trench, and
a respective plurality of elongated second-conductivity-type base connection regions which are interposed between adjacent pairs of the elongated first-conductivity-type emitter/collector regions, and which provide ohmic contact to the second-conductivity-type bulk of the semiconductor die;
wherein the elongated first-conductivity-type emitter/collector regions on the first surface of the die are orthogonal to the elongated first-conductivity-type emitter/collector regions on the second surface of the die; and
first and second current-carrying metallizations, which make contact to the emitter/collector regions on the first and second surfaces respectively; and
first and second additional metallizations, which make contact to the base connection regions on the first and second surfaces respectively.

6. The device of claim 5, wherein the first insulating trench includes a conductive field plate therein, which is electrically tied to the emitter/collector region.

7. The device of claim 5, wherein the first conductivity type is n-type.

8. The device of claim 5, wherein the semiconductor die is silicon.

9. A symmetrically-bidirectional power bipolar transistor device, comprising:
a p-type semiconductor die having, on both first and second surfaces thereof, both
a respective plurality of elongated n-type emitter/collector regions, each of which is laterally surrounded by a first insulating trench, and
a respective plurality of elongated p-type base connection regions which are interposed between adjacent pairs of the elongated n-type emitter/collector regions, and are insulated from the emitter/collector regions by the first insulating trench;
wherein the elongated n-type emitter/collector regions on the first surface of the die are orthogonal to the elongated n-type emitter/collector regions on the second surface of the die.

10. The device of claim 9, wherein the first insulating trench includes a conductive field plate therein, which is electrically tied to the emitter/collector region.

11. The device of claim 9, wherein the semiconductor die is silicon.
